(19) United States
(12) Patent Application Publication
(10) Pub. No.: US 2015/0050816 A1
(43) Pub. Date: Feb. 19, 2015

(54) METHOD OF ELECTROCHEMICALLY PREPARING SILICON FILM

(71) Applicant: Korea Atomic Energy Research Institute, Daejeon (KR)

(72) Inventors: Sang Eun Bae, Sejong (KR); Jong-Yun Kim, Daejeon (KR); Jei-Won Yeon, Daejeon (KR); Tae-Hong Park, Daejeon (KR); Kyuseok Song, Daejeon (KR); Dae Hyeon Kim, Daejeon (KR); Young Hwan Cho, Daejeon (KR); Yong Joon Park, Daejeon (KR); Yeong-Keong Ha, Sejong (KR)

(21) Appl. No.: 14/463,584

(22) Filed: Aug. 19, 2014

(30) Foreign Application Priority Data
Aug. 19, 2013 (KR) 10-2013-0097739
Jul. 23, 2014 (KR) 10-2014-0092967

(51) Int. Cl. H01L 21/02

(52) U.S. Cl. CPC H01L 21/02203; H01L 21/02164; H01L 21/02343
USPC 438/787

(57) ABSTRACT

A method of preparing a silicon thin film, silicon thin film prepared using the method, and an electronic device including the silicon thin film are provided. The method includes applying an oxidized silicon element solution to a substrate and sintering the silicon oxide film to prepare a compact silicon oxide thin film, electrochemically reducing the silicon oxide thin film to form a porous silicon film, and re-sintering the porous silicon film. Therefore, the silicon thin film used in semiconductors, solar cells, secondary batteries and the like can be easily prepared at a low cost with a smaller number of processes than the conventional methods, and thus price competitiveness of products can be enhanced.

### CROSS-REFERENCE TO RELATED APPLICATION

This application claims priority to and the benefit of Korean Patent Application Nos. KR10-2013-0097739, filed on Aug. 19, 2013 and 10-2014-0092967, filed on Jul. 23, 2014, the disclosures of which are incorporated herein by reference in their entirety.

### BACKGROUND

1. Field

The present disclosure relates to methods of preparing a silicon thin film, a silicon thin film prepared using the same, and an electronic device including the silicon thin film.

2. Discussion of Related Art

With rapid development of the IT industry in the 21^{st} century, the silicon semiconductor industry is booming to the maximum extent. Silicon semiconductors are produced by subjecting silica such as naturally existing sand, that is, an oxidized silicon element, to an electrolytic reduction process. More particularly, a silicon semiconductor may be prepared using various processes such as preparation of polysilicon, preparation of monocrystalline ingots, manufacture of silicon wafers through cutting, polishing, patterning, and the like.

However, such conventional techniques consume a great amount of energy and their multiple manufacturing processes require large facilities, long process time, and high cost.

Meanwhile, much attention has been paid to new clean energy due to sky-high oil prices and increasing environmental concerns. In particular, the importance of solar cells has grown since they are environmentally friendly and inexhaustible unlike other energy sources. Solar cells are classified into crystalline solar cells using a wafer used in the semiconductor and thin-film solar cells using deposition technologies on a substrate such as a transparent substrate. Although crystalline solar cells currently have a high market share, the market share of thin-film solar cells is expected to increase in the near future due to their high efficiency and low cost.

A method of preparing a silicon thin film used in the solar cells includes fusing silica, which is a sand component, at a high temperature, electrochemical reducing the silica to prepare silicon, preparing the silicon in the form of an ingot, and cutting the silicon ingot to a desired size to prepare silicon wafers or thin films having a desired size. Also, a silicon thin film may be prepared using a method such as vapor deposition. However, this method requires a very high temperature and long process time since they are performed through many processes including a pretreatment process. Therefore, the production cost of the solar cells and semiconductors using silicon may increase, resulting in a decrease in price competitiveness.

A silicon thin film is applicable in a wide variety of fields. For example, it may be used to manufacture a thin-film nuclear fuel used in research reactors in the field of nuclear power. Korean Registered Patent No. 10-1196224 discloses a method of forming silicon coating layer at U—Mo alloy powder.

The foregoing disclosure is to provide general background information, however, does not constitute an admission of prior art.

### SUMMARY

Therefore, the present inventors have easily prepared silicon thin films, which are used in semiconductor or solar cells, from oxidized silicon element such as sand with a smaller number of processes and lower energy consumption with respect to conventional methods to prepare silicon thin film. Accordingly, the present invention is directed to a method of preparing a silicon thin film capable of highly reducing the production cost of semiconductors or solar cells.

However, the technical aspects of the present invention are not limited thereto, and other aspects of the present invention which are not disclosed herein will become more apparent to those of ordinary skill in the art by describing in detail embodiments thereof.

One aspect of the invention provides a method of preparing a silicon thin film, the method comprising: providing a silicon oxide film over a substrate; and electrochemically reducing silicon oxide contained in the silicon oxide film in a liquid electrolyte to form a porous film.

In the foregoing method, providing the silicon oxide film may comprise: providing silicon oxide liquid comprising silicon oxide; applying the silicon oxide liquid on the substrate to provide the silicon oxide film over the substrate; and sintering the silicon oxide film. The silicon oxide liquid or the liquid electrolyte comprises a compound comprising at least one selected from the group consisting of carbon (C), boron (B), nitrogen (N), aluminum (Al), phosphorus (P), sulfur (S), gallium (Ga), arsenic (As), selenium (Se), indium (In), tin (Sn), antimony (Sb), tellurium (Te), wherein the resulting silicon thin film further comprises at least one selected from the group consisting of carbon (C), boron (B), nitrogen (N), aluminum (Al), phosphorus (P), sulfur (S), gallium (Ga), arsenic (As), selenium (Se), indium (In), tin (Sn), antimony (Sb), tellurium (Te). Applying the silicon oxide liquid may comprise at least one method selected from the group consisting of spin coating, inkjet coating, casting, brushing, dipping, physical vapor deposition, and chemical vapor deposition. The silicon oxide liquid may comprise a carbon compound, wherein the resulting silicon thin film comprises carbon.

In the foregoing method, the silicon oxide liquid or the liquid electrolyte may comprise a compound comprising at least one selected from the group consisting of lithium (Li), sodium (Na), potassium (K), rubidium (Rb), cesium (Cs), francium (Fr), beryllium (Be), magnesium (Mg), calcium (Ca), strontium (Sr), barium (Ba), radium (Ra), boron (B), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), arsenic (As), selenium (Se), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), lanthanum (La), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), actinium (Ac), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), thorium (Th), protactinium (Pa), uranium (U), neptunium (Np), plutonium (Pu), americium (Am), and curium (Cm).

The foregoing method may further comprise removing the liquid electrolyte from the silicon thin film, wherein removing the liquid electrolyte involves at least one of boiling the liquid electrolyte under a pressure of less than 760 Torr and washing the liquid electrolyte with liquid containing water. Providing the silicon oxide liquid may comprise mixing silicon oxide with a solvent.

Still in the foregoing method, mixing silicon oxide may comprise mixing at least one material selected from the group consisting of sand, glass, quartz, rock, ceramic, silica (SiO₂), tetraethoxysilane (TEOS), tetramethoxysilane, a silicon alkoxy, and silicon tetrachloride. The solvent may comprise in at least one selected from the group consisting of water, lithium hydroxide, sodium hydroxide, potassium hydroxide, calcium hydroxide, rubidium hydroxide, strontium hydroxide, cesium hydroxide, barium hydroxide, hydrofluoric acid, hydrochloric acid, sulfuric acid, nitric acid, phosphoric acid, sodium silicate, ethanol, methanol, benzene, toluene, hexane, pentane, cyclohexane, chloroform, diethyl ether, dichloromethane (DCM), tetrahydrofuran (THF), ethyl acetate, acetone, acetonitrile, dimethylformamide (DMF), dimethylsulfoxide (DMSO), and propylene carbonate. The substrate may comprise at least one selected from the group consisting of a metal, carbon, and silicon.

Further in the foregoing method, the liquid electrolyte may comprise at least one selected from the group consisting of LiCl, KCl, NaCl, RbCl, CsCl, FrCl, CaCl₂, MgCl₂, SrCl₂, BaCl₂, AlCl₃, ThCl₃, LiF, KF, NaF, RbF, CsF, FrF, CaF₂, MgF₂, SrF₂, BaF₂, AlF₃, ThF₃, LiPF₆, LiBr, NaBr, KBr, RbBr, CsBr, FrBr, LiI, NaI, Kl, RbI, CsI, and FrI. The liquid electrolyte may comprise at least one selected from the group consisting of acetonitrile, tetrafluoroborate, 1-butyl-3-methylimidazolium chloride, 1-butyl-1-methylpyrrolidinium bis(trifluoromethylsulfonyl)imide, 1-butylpyridinium chloride, choline chloride, 1-butyl-3-methylimidazolium chloride, dimethylethylphenylammonium bromide, dimethylformamide, dimethyl sulfone, dimethyl sulfoxide, ethylene carbonate, dimethyl carbonate, ethyl-methyl carbonate, ethylene-diaminetetra-acetic acid tetrasodium, ethylene glycol, 1-ethyl-3-methylimidazolium, 1-octyl-1-methyl-pyrrolidinium bis(trifluoromethylsulfonyl)imide, hexafluorophosphate, 1-propyl-3-methylimidazolium chloride, trihexyl-tetradecyl-phosphonium bis(trifluoromethylsulfonyl)imide, tetrabutylammonium chloride bis(trifluoromethylsulfonyl)imide, tetrahydrofuran, and trimethylphenylammonium chloride. Sintering the porous silicon film may comprise heating the porous silicon film at 1,350° C. or higher for 1 second or more.

Another aspect of the invention provides a method of preparing a thin film, the method comprising: providing, over a substrate, an oxide film comprising one selected from the group consisting of lithium (Li), sodium (Na), potassium (K), rubidium (Rb), cesium (Cs), francium (Fr), beryllium (Be), magnesium (Mg), calcium (Ca), strontium (Sr), barium (Ba), radium (Ra), boron (B), carbon (C), aluminum (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), arsenic (As), selenium (Se), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), lanthanum (La), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), actinium (Ac), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), thorium (Th), protactinium (Pa), uranium (U), neptunium (Np), plutonium (Pu), americium (Am), and curium (Cm); and electrochemically reducing the oxide contained in the oxide film in a liquid electrolyte to form a porous film.

According to an aspect of the present invention, a method of preparing a silicon thin film is provided. Here, the method includes (a) preparing a silicon oxide thin film by applying oxidized silicon element solution to a substrate and its sintering, and (b) electrochemically reducing the silicon oxide thin film in a liquid electrolyte to form a porous silicon film.

In this case, the method of preparing a silicon thin film according to one embodiment of the present invention may further include (c) re-sintering the porous silicon film to form a flat silicon thin film after step (b).

Also, the method of preparing a silicon thin film according to one embodiment of the present invention further includes electrodepositing carbon by adding an oxidized carbon element to the oxidized silicon element solution in step (a) or adding an oxidized carbon element to the liquid electrolyte in step (b).

In the method of preparing a silicon thin film according to one embodiment of the present invention, at least one selected from the group consisting of boron (B), nitrogen (N), aluminum (Al), phosphorus (P), sulfur (S), gallium (Ga), arsenic (As), selenium (Se), indium (In), tin (Sn), antimony (Sb), tellurium (Te), and their oxidized elements thereof may be further added to the oxidized silicon element solution in step (a).

Also, the method of preparing a silicon thin film according to another embodiment of the present invention further includes removing the liquid electrolyte from the silicon thin film by boiling the liquid electrolyte in a container having a low pressure of less than 760 Torr or by washing with an aqueous solution after step (b).

According to still another embodiment of the present invention, the oxidized silicon element in step (a) may be at least one material selected from the group consisting of sand, glass, quartz, rock, ceramic, silica (SiO₂), tetraethoxysilane (TEOS), tetramethoxysilane, a silicon alkoxy, and silicon tetrachloride.

According to still another embodiment of the present invention, the oxidized silicon element solution in step (a) may be prepared by dissolving the material selected from the group consisting of sand, glass, quartz, rock, ceramic, silica (SiO₂), tetraethoxysilane (TEOS), tetramethoxysilane, a silicon alkoxy, and silicon tetrachloride in at least one selected from the group consisting of water, lithium hydroxide, sodium hydroxide, potassium hydroxide, calcium hydroxide, rubidium hydroxide, strontium hydroxide, cesium hydroxide, barium hydroxide, hydrofluoric acid, hydrochloric acid, sulfuric acid, nitric acid, phosphoric acid, sodium silicate, ethanol, methanol, benzene, toluene, hexane, pentane, cyclohexane, chloroform, diethylether, dichloromethane (DCM), tetrahydrofuran (THF), ethyl acetate, acetone, acetonitrile, dimethylformamide (DMF), dimethylsulfoxide (DMSO), and propylene carbonate.

According to still another embodiment of the present invention, the substrate in step (a) may be at least one selected from the group consisting of a metal, carbon, and silicon.

According to still another embodiment of the present invention, the applying of the oxidized silicon element solution in step (a) may be performed using at least one method selected from the group consisting of spin coating, inkjet coating, casting, brushing, dipping, physical vapor deposition, and chemical vapor deposition.

According to still another embodiment of the present invention, the liquid electrolyte in step (b) may be a high-temperature molten salt obtained by melting a salt at a high temperature.

According to still another embodiment of the present invention, the high-temperature molten salt may be at least one selected from the group consisting of LiCl, KCl, NaCl, RbCl, CsCl, FrCl, CaCl₂, MgCl₂, SrCl₂, BaCl₂, AlCl₃, ThCl₃, LiF, KF, NaF, RbF, CsF, FrF, CaF₂, MgF₂, SrF₂, BaF₂, AlF₃, ThF₃, LiPF₆, LiBr, NaBr, KBr, RbBr, CsBr, FrBr, LiI, NaI, Kl, RbI, CsI, and FrI.

According to still another embodiment of the present invention, the liquid electrolyte may be at least one selected from the group consisting of acetonitrile, tetrafluoroborate, 1-butyl-3-methylimidazolium chloride, 1-butyl-1-methylpyrrolidinium bis(trifluoromethylsulfonyl)imide, 1-butylpyridinium chloride, choline chloride, 1-butyl-3-methylimidazolium chloride, dimethylethylphenylammonium bromide, dimethylformamide, dimethyl sulfone, dimethyl sulfoxide, ethylene carbonate, dimethyl carbonate, ethyl-methyl carbonate, ethylene-diaminetetra-acetic acid tetrasodium, ethylene glycol, 1-ethyl-3-methylimidazolium, 1-octyl-1-methyl-pyrrolidinium bis(trifluoromethylsulfonyl)imide, hexafluorophosphate, 1-propyl-3-methylimidazolium chloride, trihexyl-tetradecyl-phosphonium bis(trifluoromethylsulfonyl)imide, tetrabutylammonium chloride bis(trifluoromethylsulfonyl)imide, tetrahydrofuran, and trimethylphenylammonium chloride.

According to still another embodiment of the present invention, the sintering of the silicon oxide film in step (a) may be performed by heating the silicon oxide film at 100° C. or higher for 1 second or more, and the re-sintering of the porous silicon film in step (c) may be performed by heating the porous silicon film at 1,350° C. or higher for 1 second or more.

According to still another embodiment of the present invention, the oxidized silicon element may be replaced with at least one selected from the group consisting of lithium (Li), sodium (Na), potassium (K), rubidium (Rb), cesium (Cs), francium (Fr), beryllium (Be), magnesium (Mg), calcium (Ca), strontium (Sr), barium (Ba), radium (Ra), boron (B), carbon (C) aluminum (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), arsenic (As), selenium (Se), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), lanthanum (La), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), actinium (Ac), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), thorium (Th), protactinium (Pa), uranium (U), neptunium (Np), plutonium (Pu), americium (Am), curium (Cm), and their oxidized elements.

According to still another embodiment of the present invention, the oxidized carbon element may be replaced with at least one selected from the group consisting of lithium (Li), sodium (Na), potassium (K), rubidium (Rb), cesium (Cs), francium (Fr), beryllium (Be), magnesium (Mg), calcium (Ca), strontium (Sr), barium (Ba), radium (Ra), boron (B), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), arsenic (As), selenium (Se), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), lanthanum (La), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), actinium (Ac), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), thorium (Th), protactinium (Pa), uranium (U), neptunium (Np), plutonium (Pu), americium (Am), curium (Cm), and their oxidized elements.

According to yet another embodiment of the present invention, the electrochemical reduction of the silicon oxide thin film may be performed between −2.5 V and 0 V vs. Ag|Ag⁺.

According to another aspect of the present invention, a method of preparing a silicon film is provided. Here, the method includes (a) dissolving at least one material selected from the group consisting of sand, glass, quartz, rock, ceramic, silica (SiO₂), tetraethoxysilane (TEOS), tetramethoxysilane, and a silicon alkoxy in a solvent to obtain an oxidized silicon element solution, (b) preparing a powder of silica, fluorinated silica (SiFxOy) or hydroxo-fluorinated silicon (SiFₓOH_{y}) by evaporating, drying, extracting or filtering the oxidized silicon element solution, and (c) electrochemically reducing the silica, fluorinated silica (SiFxOy) or hydroxo-fluorinated silicon (SiFₓOH_{y}) in a liquid electrolyte to electrodeposit silicon onto a substrate.

According to one embodiment of the present invention, the solvent in step (a) may be at least one selected from the group consisting of water, hydrofluoric acid, lithium fluoride, sodium fluoride, potassium fluoride, rubidium fluoride, cesium fluoride, beryllium fluoride, magnesium fluoride, calcium fluoride, strontium fluoride, barium fluoride, ammonium fluoride, lithium hydroxide, sodium hydroxide, potassium hydroxide, rubidium hydroxide, cesium hydroxide, beryllium hydroxide, magnesium hydroxide, calcium hydroxide, strontium hydroxide, and barium hydroxide.

According to another embodiment of the present invention, at least one selected from the group consisting of uranium (U), thorium (Th), plutonium (Pu), carbon (C), boron (B), nitrogen (N), aluminum (Al), phosphorus (P), sulfur (S), gallium (Ga), arsenic (As), selenium (Se), indium (In), tin (Sn), antimony (Sb), tellurium (Te), and their oxidized elements thereof may be further added to the liquid electrolyte in step (c).

According to still another embodiment of the present invention, the liquid electrolyte in step (c) may be at least one high-temperature molten salt selected from the group consisting of LiCl, KCl, NaCl, RbCl, CsCl, FrCl, CaCl₂, MgCl₂, SrCl₂, BaCl₂, AlCl₃, ThCl₃, LiF, KF, NaF, RbF, CsF, FrF, CaF₂, MgF₂, SrF₂, BaF₂, AlF₃, ThF₃, LiPF₆, LiBr, NaBr, KBr, RbBr, CsBr, FrBr, LiI, NaI, Kl, RbI, CsI, and FrI.

According to still another embodiment of the present invention, the liquid electrolyte in step (c) may be at least one selected from the group consisting of acetonitrile, tetrafluoroborate, 1-butyl-3-methylimidazolium chloride, 1-butyl-1-methylpyrrolidinium bis(trifluoromethylsulfonyl)imide, 1-butylpyridinium chloride, choline chloride, 1-butyl-3-methylimidazolium chloride, dimethylethylphenylammonium bromide, dimethylformamide, dimethyl sulfone, dimethyl sulfoxide, ethylene carbonate, dimethyl carbonate, ethyl-methyl carbonate, ethylene-diaminetetra-acetic acid tetrasodium, ethylene glycol, 1-ethyl-3-methylimidazolium, 1-octyl-1-methyl-pyrrolidinium bis(trifluoromethylsulfonyl)imide, hexafluorophosphate, 1-propyl-3-methylimidazolium chloride, trihexyl-tetradecyl-phosphonium bis(trifluoromethylsulfonyl)imide, tetrabutylammonium chloride bis(trifluoromethylsulfonyl)imide, tetrahydrofuran, and trimethylphenylammonium chloride.

According to yet another embodiment of the present invention, the electrochemical reduction of step (c) may be performed between −2.5 V and 0 V vs. Ag|Ag⁺.

According to still another aspect of the present invention, a film prepared using the methods is provided.

According to yet another aspect of the present invention, a device including the film is provided.

According to one embodiment of the present invention, the device may be at least one selected from the group consisting of a semiconductor, a solar cell, a secondary battery, a fuel cell, a water electrolysis cell, a nuclear fuel of a nuclear reactor, a target for producing a radioactive isotope, a catalyst for a chemical reaction, and a sensor.

### BRIEF DESCRIPTION OF THE DRAWINGS

The above and other aspects, features and advantages of the present invention will become more apparent to those of ordinary skill in the art by describing in detail embodiments thereof with reference to the accompanying drawings, in which:

FIG. 1 is a flowchart illustrating a method of electrochemically preparing a thin film according to one embodiment of the present invention;

FIG. 2 is an image showing a coating agent obtained by dissolving silica in a sodium hydroxide solvent;

FIG. 3 is an image showing a silicon oxide thin film prepared using spin coating and sintering methods, as observed under an electron microscope;

FIG. 4 is a graph illustrating cyclic voltammograms obtained during a process of electrochemical reduction of a silicon oxide thin film in a high-temperature molten salt to prepare a silicon thin film;

FIG. 5 is an image of a silicon thin film for which a silicon oxide thin film is electrochemically reduced, as observed under a scanning electron microscope and measured by energy dispersive X rays (EDX);

FIG. 6 is a graph illustrating cyclic voltammograms according to the concentration of a carbonate ion, obtained from a silicon thin film which is prepared by forming a silicon oxide thin film to which carbonate ions are added and by electrochemically reducing the silicon oxide thin film in a high-temperature molten salt;

FIG. 7 is a graph illustrating cyclic voltammograms according to the concentration of a nitrate ion, obtained from a silicon thin film which is prepared by forming a silicon oxide thin film to which nitrate ions are added and by electrochemically reducing the silicon oxide thin film in a high-temperature molten salt;

FIG. 8 is an image of a silicon thin film prepared by electrochemically reducing an oxidized silicon element, which is obtained by dissolving and heating sand, in a liquid electrolyte (i.e., a high-temperature molten salt), thereby electrodepositing silicon, as observed under a scanning electron microscope and measured by EDX; and

FIG. 9 is an image of a silicon uranium (SiU) thin film prepared by reducing an oxidized silicon element, which is obtained by dissolving and heating sand, and an oxidized uranium element in a liquid electrolyte (i.e., a high-temperature molten salt), thereby electrodepositing the silicon and uranium, as observed under a scanning electron microscope and measured by EDX.

### DETAILED DESCRIPTION OF EMBODIMENTS

Embodiments of the present invention will be described in detail below with reference to the accompanying drawings. While the present invention is shown and described in connection with embodiments thereof, it will be apparent to those skilled in the art that various modifications can be made without departing from the scope of the invention.

Unless specifically stated otherwise, all the technical and scientific terms used in this specification have the same meanings as what are generally understood by a person skilled in the related art to which the present invention belongs. In general, the nomenclatures used in this specification and the experimental methods described below are widely known and generally used in the related art.

In general, since a semiconductor uses a silicon thin film, a process that can manufacture the silicon thin film from source materials such as sand may reduce the manufacturing cost extensively with respect to the conventional processes.

Generally speaking, silica can be electrochemically reduced into silicon in a molten salt. Also, a technology for converting quartz or glass into silicon or electrochemical converting silica powder into silicon powder, a technology for preparing a silicon quantum dot thin film by the application of silicon particles in an organic solution to a silicon substrate and thermally treating the silicon particle solution, technology for forming a silicon oxide film by exposing (dipping) a silicon substrate to (in) a solution including hydrogen peroxide after spin coating can be provided. In one embodiment, a technology for reducing an oxidized silicon element to silicon in a high-temperature molten salt after a coating process can be provided as described below.

Further, this technology for electrochemical preparing a thin film is applicable in a wide variety of fields. For example, it may be used to manufacture a thin-film nuclear fuel used in research reactors in the field of nuclear power. Such a thin-film nuclear fuel is composed of UₓMo_{y}, UₓSi_{y}, and the like. However, its manufacturing process may be complicated and its starting material may be very expensive. Therefore, the electrochemical method that can easily manufacture the thin-film nuclear fuel may reduce the operating expenses of the research reactor and cut the production cost of radioactive isotopes as anticancer drugs, and the like in the research reactor.

One aspect of the present invention is directed to a method of preparing a silicon thin film, which includes (a) preparing a silicon oxide thin film by applying an oxidized silicon element solution to a substrate and its sintering, (b) electrochemically reducing the silicon oxide thin film in a liquid electrolyte to form a porous silicon film, and (c) re-sintering the porous silicon film to form a flat silicon thin film.

According to one embodiment of the present invention, the oxidized silicon element solution is applied to a substrate, and then followed by its sintering to prepare a silicon oxide thin film. In this case, the sintering conditions are not particularly limited. For example, the sintering may be performed by heating the silicon oxide film on the substrate at 100° C. or higher for 1 second or more.

According to one embodiment of the present invention, carbon may be further electrodeposited by adding oxidized carbon elements to the oxidized silicon element solution in step (a) or adding an oxidized carbon element to the liquid electrolyte in step (b).

According to one embodiment of the present invention, a metal may also be further electrodeposited by adding the oxidized metal element in the liquid electrolyte when the silicon oxide thin film is electrochemically reduced. In this case, the metal that may be used herein may include at least one selected from the group consisting of lithium (Li), sodium (Na), potassium (K), rubidium (Rb), cesium (Cs), francium (Fr), beryllium (Be), magnesium (Mg), calcium (Ca), strontium (Sr), barium (Ba), radium (Ra), boron (B), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), arsenic (As), selenium (Se), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), lanthanum (La), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), actinium (Ac), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), thorium (Th), protactinium (Pa), uranium (U), neptunium (Np), plutonium (Pu), americium (Am), and curium (Cm), but the present invention is not limited thereto.

According to one embodiment of the present invention, a small amount of boron (B), nitrogen (N), aluminum (Al), phosphorus (P), sulfur (S), gallium (Ga), arsenic (As), selenium (Se), indium (In), tin (Sn), antimony (Sb), tellurium (Te), or their oxidized elements thereof may be added to the oxidized silicon element solution. When the oxidized silicon element solution is applied in a state in which such an element is added to the oxidized silicon element solution, it is possible to chemically dope the silicon thin film.

The method according to one embodiment of the present invention may further include evaporating and removing the liquid electrolyte from the silicon thin film after the electrochemical reduction. In this case, the liquid electrolyte may be heated to a temperature less than the boiling point of the liquid electrolyte in a container having a low pressure of less than 760 Torr.

The types of oxidized silicon elements that may be used herein are not particularly limited as long as they can be widely used in the related art. For example, the oxidized silicon element may be a silicon precursor such as a natural material including silica (e.g., sand, glass, quartz, ceramic, or rock), silica (SiO₂), tetraethoxysilane (TEOS), tetramethoxysilane, a silicon alkoxy, or silicon tetrachloride. In particular, a thin film having a perfect defect-free structure may be prepared using the oxidized silicon element such as tetraethoxysilane (TEOS).

According to one embodiment of the present invention, at least one selected from the group consisting of lithium (Li), sodium (Na), potassium (K), rubidium (Rb), cesium (Cs), francium (Fr), beryllium (Be), magnesium (Mg), calcium (Ca), strontium (Sr), barium (Ba), radium (Ra), boron (B), carbon (C) aluminum (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), arsenic (As), selenium (Se), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), lanthanum (La), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), actinium (Ac), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), thorium (Th), protactinium (Pa), uranium (U), neptunium (Np), plutonium (Pu), americium (Am), curium (Cm), and their oxidized elements may be used instead of the oxidized silicon element.

In the present invention, the oxidized silicon element is dissolved in a solvent to be used as a plating agent. In this case, the types of solvents that may be used herein are not particularly limited as long as they can be widely used in the related art. For example, the solvent may be an aqueous solution such as water, lithium hydroxide, sodium hydroxide, potassium hydroxide, calcium hydroxide, rubidium hydroxide, strontium hydroxide, cesium hydroxide, barium hydroxide, hydrofluoric acid, hydrochloric acid, sulfuric acid, nitric acid, phosphoric acid, or sodium silicate, or an organic solvent such as ethanol, methanol, benzene, toluene, hexane, pentane, cyclohexane, chloroform, diethyl ether, dichloromethane (DCM), tetrahydrofuran (THF), ethyl acetate, acetone, acetonitrile, dimethylformamide (DMF), dimethylsulfoxide (DMSO), or propylene carbonate.

In this case, the concentration of the oxidized silicon element may be in a range of 0.1% by weight to 50% by weight. In the present invention, the substrate to which the oxidized silicon element solution is applied may be a conductor such as a metal, carbon, or a semiconductor substrate such as silicon.

In the present invention, the applying process of the oxidized silicon element solution to a substrate is not particularly limited, and thus may be a coating method known in the related art. For example, the applying process may be performed using a method such as spin coating, inkjet coating, casting, brushing, dipping, physical vapor deposition, or chemical vapor deposition. Spin coating is most preferred.

In particular, for applying the oxidized silicon element solution to a substrate using spin coating, the spin coating solution may be dropped on the substrate installed in a spin coater using a pipette while rotating the spin coater at a rate of 500 to 10,000 rpm to form an oxide thin film on the substrate. In this case, the thickness of the thin film may be controlled by adjusting the rotation speed or the concentration of the spin coating solution.

In the present invention, the silicon thin film may be directly prepared by coating the oxide to a desired thickness using a method such as spin coating and by electrochemically reducing the oxide in an electrolyte such as a high-temperature molten salt.

In the present invention, a molten salt (a high-temperature molten salt) obtained by melting a salt at a high temperature may be used as the liquid electrolyte. In this case, the high-temperature molten salt may be at least one selected from the group consisting of LiCl, KCl, NaCl, RbCl, CsCl, FrCl, CaCl₂, MgCl₂, SrCl₂, BaCl₂, AlCl₃, ThCl₃, LiF, KF, NaF, RbF, CsF, FrF, CaF₂, MgF₂, SrF₂, BaF₂, AlF₃, ThF₃, LiPF₆, LiBr, NaBr, KBr, RbBr, CsBr, FrBr, LiI, NaI, Kl, RbI, CsI, and FrI.

Also, the liquid electrolyte may be at least one selected from the group consisting of acetonitrile, tetrafluoroborate, 1-butyl-3-methylimidazolium chloride, 1-butyl-1-methylpyrrolidinium bis(trifluoromethylsulfonyl)imide, 1-butylpyridinium chloride, choline chloride, 1-butyl-3-methylimidazolium chloride, dimethylethylphenylammonium bromide, dimethylformamide, dimethyl sulfone, dimethyl sulfoxide, ethylene carbonate, dimethyl carbonate, ethyl-methyl carbonate, ethylene-diaminetetra-acetic acid tetrasodium, ethylene glycol, 1-ethyl-3-methylimidazolium, 1-octyl-1-methyl-pyrrolidinium bis(trifluoromethylsulfonyl)imide, hexafluorophosphate, 1-propyl-3-methylimidazolium chloride, trihexyl-tetradecyl-phosphonium bis(trifluoromethylsulfonyl)imide, tetrabutylammonium chloride bis(trifluoromethylsulfonyl)imide, tetrahydrofuran, and trimethylphenylammonium chloride.

According to one embodiment of the present invention, the porous silicon film may be re-sintered to form a flat and highly dense silicon thin film. In this case, the re-sintering conditions are not particularly limited. For example, the re-sintering may be performed by heating the porous silicon film at 1,350° C. or higher for 1 second or more.

In the present invention, the electrochemical reduction may be performed between −2.5 V and 0 V vs. Ag|Ag⁺.

According to one embodiment of the present invention, the silicon thin film may be prepared by adding the oxidized silicon element powder to the liquid electrolyte and then by performing an electrodeposition reaction of silicon on an electrode.

In the present invention, a powder obtained by dissolving a silica-containing natural material (e.g., sand, glass, quartz, or rock) in hydrofluoric acid and by drying or evaporating the natural material containing solution may be added to the liquid electrolyte to electrodeposit silicon.

In the present invention, uranium (U), thorium (Th), plutonium (Pu), carbon (C), boron (B), nitrogen (N), aluminum (Al), phosphorus (P), sulfur (S), gallium (Ga), arsenic (As), selenium (Se), indium (In), tin (Sn), antimony (Sb), tellurium (Te), or their oxidized elements thereof may be added to the liquid electrolyte together with the oxidized silicon element powder to perform an electrodeposition reaction, thereby preparing a silicon film including the above-listed elements.

Also, the present invention provides a film prepared using the method, and a device including the film. In this case, the device may be a semiconductor, a solar cell, a secondary battery, a fuel cell, a water electrolysis cell, a nuclear fuel of a nuclear reactor, a target for producing a radioactive isotope, a catalyst for chemical reaction, or a sensor, but the present invention is not limited thereto. Particularly, according to one embodiment of the present invention, the cost and the number of processes may be highly reduced in a process of preparing a flexible silicon thin film for solar cells or an electrode for lithium secondary batteries.

Hereinafter, the method of electrochemically preparing a silicon thin film according to one embodiment of the present invention will be described in further detail with reference to the accompanying drawings.

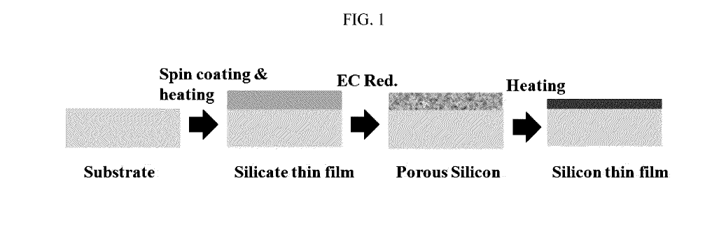

FIG. 1 is a flowchart illustrating a method of electrochemically preparing a thin film according to one embodiment of the present invention. According to one embodiment of the present invention, various concentrations of the oxidized silicon element (e.g., silica) may be plated once or several times on conductor substrates such as a metal, carbon, or silicon using methods such as spin coating and sintering. The silicon oxide thin films having various thicknesses may be prepared using such methods. Also, the porous silicon thin film may be prepared by electrochemically reducing the silicon oxide thin film in an electrochemical cell. The flat and highly dense silicon thin film may be prepared by applying a high temperature to the prepared porous silicon thin film using a method such as sintering.

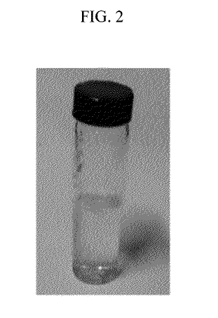

FIG. 2 is an image showing a coating agent (i.e., a plating agent) obtained by dissolving an oxidized silicon element such as silica in a sodium hydroxide solvent. The silica thin film may be formed on the substrate using such a solution used in methods such as spin coating, inkjet coating, casting, brushing, dipping, physical vapor deposition, and chemical vapor deposition.

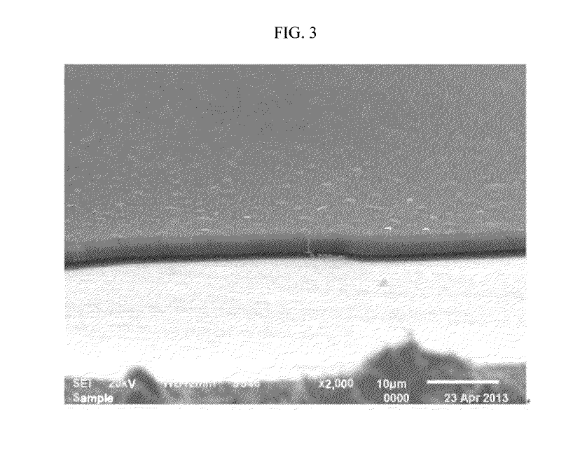

FIG. 3 is an image showing a silicon oxide thin film prepared using a spin coating method, as observed under an electron microscope. The desired silicon oxide thin film having a proper thickness may be prepared by adjusting the concentration of the coating agent, the kind of the coating agent, a coating method, a coating rate, and the like.

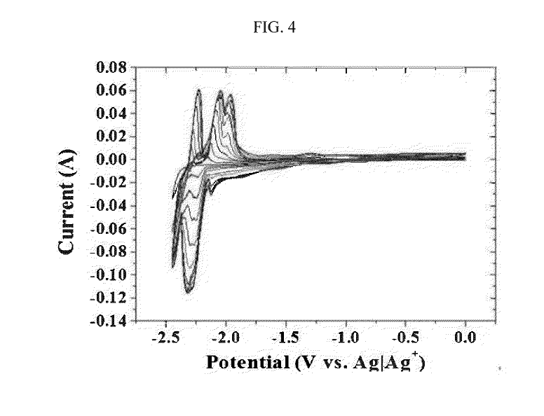

FIG. 4 is a graph illustrating cyclic voltammograms obtained from the prepared silicon oxide thin film in a high-temperature molten salt. It was revealed that no current signal is observed in the first cycle due to a dielectric property of the silica thin film, but a charging current of lithium ions increases at −2.3 V and a discharging current of the lithium ions increases at −2.0 V as the number of cycle increases. It was revealed that the charging/discharging currents of the lithium ions continue to increase up to the 7^{th} cycle and remain constant after the 8^{th} cycle. This increase of the charging/discharging currents of the lithium ions supports that the silica thin film, that is initially an insulator, is reduced into the silicon thin film that is a conductor as the number of cycle increases.

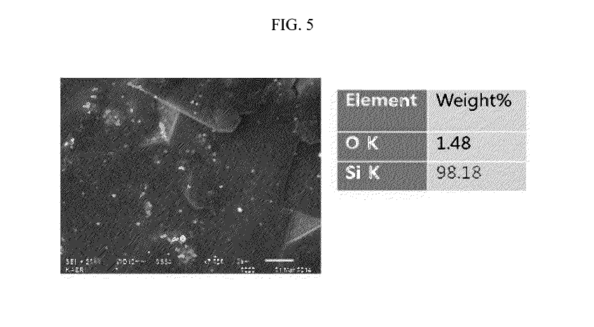

FIG. 5 is an image of a silicon thin film prepared using a method such as spin coating, sintering, electrochemical reduction, or electrolyte evaporation, as observed under a scanning electron microscope and measured by EDX. From the EDX measurement results, it could be seen that at least 98% of the silica thin film is reduced into silicon.

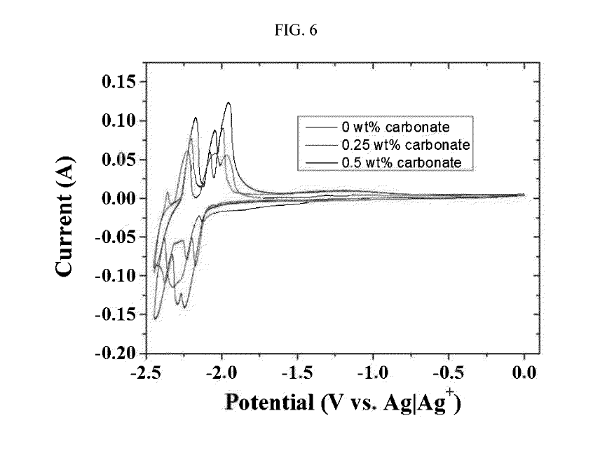

FIG. 6 is a graph illustrating a cyclic voltammograms obtained after a silicon oxide thin film prepared by adding carbonate ions to a silica coating agent is dipped to a high-temperature molten salt and electrochemically reduced. It could be seen that as the concentration of the carbonate ions increases, a charging current of lithium ions increases in the vicinity of −2.3 V, and a discharging current of the lithium ions increases in the vicinity of −2.0 V. This is because the electrical conductivity of silicon increases due to co-deposited carbon which is produced by the reduction of the carbonate ions.

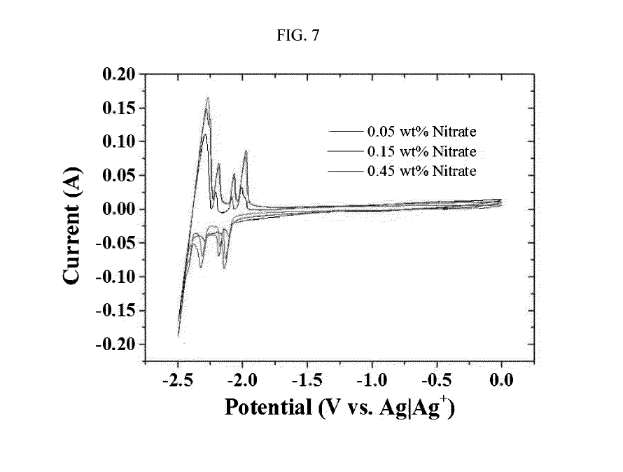

FIG. 7 is a graph illustrating cyclic voltammograms obtained after a silicon oxide thin film prepared by adding nitrate ions to a silica coating agent is immersed to a high-temperature molten salt and electrochemically reduced. It could be seen that as the concentration of the nitrate ions increases, a charging current of lithium ions increases in the vicinity of −2.3 V, and a discharging current of the lithium ions increases in the vicinity of −2.0 V. This is because the electrical conductivity of the silicon thin film increases as the concentration of the nitrogen, which is produced by the reduction of the nitrate ions, increases in the silicon thin film. In other words, the silicon thin film may be easily doped with nitrogen, thereby producing n-type silicon.

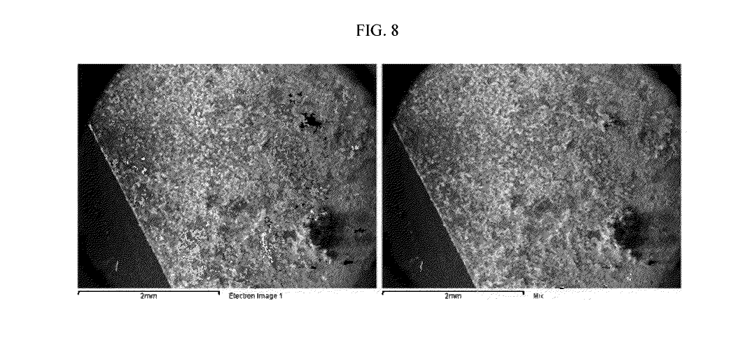

FIG. 8 is an image of a silicon (Si) thin film electrodeposited from oxidized silicon elements, which are obtained by dissolving and heating sand, dissolved in a liquid electrolyte (i.e., a high-temperature molten salt), as observed under a scanning electron microscope and measured by EDX. It could be seen that an electrodeposit is formed over a surface of an electrode as a whole. From the results obtained by mapping the electrodeposit using EDX, it could be seen that the entire surface of the electrode is coated with silicon. This indicates that the silicon thin film may be prepared by dissolving a precursor, obtained from sand, in a high-temperature molten salt and by electrodepositing the precursor.

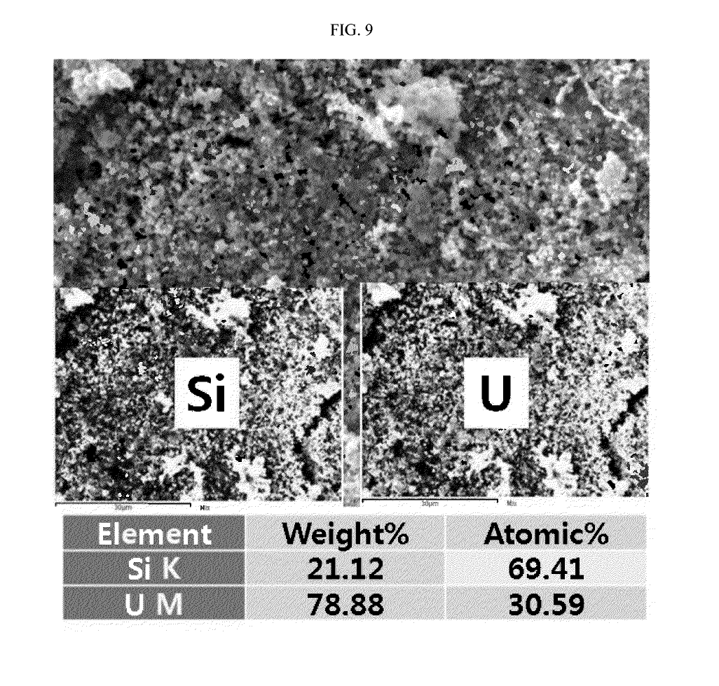

FIG. 9 is an image of a silicon uranium (SiU) thin film prepared by electrochemically reducing oxidized silicon elements, which are obtained by dissolving and heating sand, and oxidized uranium elements dissolved in a liquid electrolyte (i.e., a high-temperature molten salt), as observed under a scanning electron microscope and measured by EDX. It could be seen that the thin film electrodeposited from the high-temperature molten salt grows as a whole. From the EDX results, it could be seen that SiU is electrodeposited.

Hereinafter, the present invention will be described in further detail with reference to the following preferred Examples. However, it should be understood that the following Examples are given by way of illustration of the present invention only, and are not intended to limit the scope of the present invention, as apparent to those skilled in the art.

### EXAMPLES

### Example 1

### Preparation of Silicon Thin Film

1-1. Preparation of Silica Thin Film

900 mg of silica powder was dissolved into 18 ml of a sodium hydroxide solvent, and kept for two days until the silica was completely dissolved, thereby preparing a spin coating solution (see FIG. 2).

A tungsten substrate was attached to a spin coater, and the spin coating solution was dropped on the tungsten substrate using a pipette while rotating the tungsten substrate at a rate of 500 to 10,000 rpm to form a silica thin film on the tungsten substrate. Thereafter, the coated silica thin film was dried and then sintered by heating at 130° C. for an hour.

In this case, it was confirmed under an electron microscope that the thickness of the silica thin film was in proportion to the concentration of silica dissolved in the spin coating solution, and was in inverse proportion to the rotation speed of the spin coater (see FIG. 3).

1-2. Electrochemical Reduction of Silica Thin Film

To produce a porous silicon thin film by electrochemically reducing a silica thin film coated with spin coating and sintering methods, an electrochemical cell was set up.

The electrochemical cell was composed of the LiCl—KCl high-temperature molten salt, the silica thin film, vitreous carbon, and Ag|Ag⁺ as the electrolyte, the working electrode, the counter electrode, and the reference electrode, respectively.

The coated silica thin film was reduced into silicon using a cyclic voltammetric method, as represented by the following electrochemical formula.

SiO₂(s)→Si(s)+2O²⁻

From the results of cyclic voltammetry, it was revealed that the charging/discharging currents of lithium ions into/from the silicon increased in the vicinity of −2.3 V and −2.0 V as the cycle number increased, as shown in FIG. 4. This means that silica was reduced into silicon.

1-3. Re-Sintering of Porous Silicon Film

Then, the porous silicon film was sintered by heating at 1,450° C., a temperature at which silicon melts, for an hour to obtain a flat and clean silicon thin film (see FIG. 5).

### Example 2

### Preparation of Carbon-Added Silicon Thin Film

900 mg of silica powder, and 0% by weight, 0.25% by weight and 0.5% by weight of potassium carbonate were separately added to three vials containing 18 ml sodium hydroxide solvent, and kept for two days until the silica and potassium carbonate were completely dissolved, thereby preparing a spin coating solution.

A tungsten substrate was attached to a spin coater, and the spin coating solution was dropped on the tungsten substrate using a pipette while rotating the tungsten substrate at a rate of 500 to 10,000 rpm to form a silica thin film on the tungsten substrate. Thereafter, the coated silica thin film was dried and then sintered by heating at 130° C. for an hour.

To produce a porous silicon thin film by electrochemically reducing the silica thin film prepared with spin coating and sintering methods, an electrochemical cell was set up.

The electrochemical cell was composed of the LiCl—KCl high-temperature molten salt, the silica thin film to which the carbonate was added, vitreous carbon and Ag|Ag⁺ as the electrolyte, the working electrode, the counter electrode, and the reference electrode, respectively.

The coated silica thin film, to which the carbonate was added, was reduced

From the results of cyclic voltammetry, it was revealed that the charging/discharging currents of lithium ions into/from the silicon increased in the vicinity of −2.3 V and −2.0 V as the concentration of the added carbonate ions increased, as shown in FIG. 6.

This means that an amount of the reduced carbon increased as the concentration of the carbonate ions increased, which resulted in an increase in electrical conductivity of the silicon.

Then, the porous silicon film was sintered by heating at 1,450° C., a temperature at which silicon melts, for an hour to obtain a flat and clean silicon-carbon thin film.

### Example 3

### Silicon Doping

First of all, 900 mg of silica powder, and 0.05% by weight, 0.15% by weight and 0.45% by weight of potassium nitrate were separately added to three vials containing 18 ml sodium hydroxide solvent, and kept for two days until the silica and potassium nitrate were completely dissolved, thereby preparing a spin coating solution.

A tungsten substrate was attached to a spin coater, and the spin coating solution was dropped on the tungsten substrate using a pipette while rotating the tungsten substrate at a rate of 500 to 10,000 rpm to form a silica thin film, to which nitrate ions was added, on the tungsten substrate. Thereafter, the coated silica thin film was dried and then sintered by heating at 130° C. for an hour.

To produce a porous N-doped silicon thin film by electrochemically reducing the silica thin film prepared with spin coating and sintering methods, an electrochemical cell was set up.

The electrochemical cell was composed of the LiCl—KCl high-temperature molten salt, the silica thin film to which the nitrate ions were added, vitreous carbon, and Ag|Ag⁺ as the electrolyte, the working electrode, the counter electrode, and the reference electrode, respectively.

The silica thin film, to which the nitrate ions were added, coated by spin coating method was reduced into silicon-nitrogen using cyclic voltammetric method, as represented by the following electrochemical formula.

SiO₂(s)+KNO₃(s)N-doped Si(s)+5O²⁻+K⁺

From the results of cyclic voltammetry, it was revealed that the charging/discharging currents of lithium ions into/from the thin film increased in the vicinity of −2.3 V and −2.0 V as the concentration of the added nitrate ion increased, as shown in FIG. 7. This means that an amount of the reduced nitrogen increased as the concentration of the nitrate ions increased, which resulted in an increase in electrical conductivity of the silicon.

Then, the porous silicon film was sintered by heating at 1,450° C., a temperature at which silicon melts, for an hour to obtain a flat and clean silicon thin film.

### Example 4

### Preparation of Silicon Thin Film from Sand

1.6 g of sand was added to 8 ml of 49% HF, and kept for a week until the sand was completely dissolved. Then, the resulting solution was heated to separate the solute from the solvent, thereby recovering a white oxidized silicon element in the form of a powder.

Then, the recovered oxidized silicon element powder was dissolved at a concentration of 1.5% by weight in a LiCl—KCl high-temperature molten salt, and an electrochemical cell was set up using the tungsten substrate, vitreous carbon, and Ag|Ag⁺ as the working electrode, the counter electrode, and reference electrode, respectively.

A constant potential of −1.9 V, at which silicon is able to be electrodeposited, was applied to the tungsten substrate (a working electrode) for an hour to electrodeposit the silicon. As the chronoamperometric method proceeded, the oxidized silicon element dissolved in the high-temperature molten salt was electrodeposited as silicon, as represented by the following electrochemical formula.

SiFₓO_{y}→Si(s)+xF⁻+yO²⁻

The reduced silicon electrodeposit was investigated using a scanning electron microscope and an EDX method. As a result, it was revealed that silicon was electrodeposited onto the working electrode, as shown in FIG. 8.

### Example 5

### Preparation of Silicon-Uranium Thin Film

Oxidized silicon element powder was prepared in the same manner as in Example 4. Thereafter, 1.5% by weight of the oxidized silicon element powder and 1.5% by weight of uranium chloride were dissolved together in a LiCl—KCl high-temperature molten salt. A tungsten substrate, vitreous carbon, and Ag|Ag⁺ were used as a working electrode, a counter electrode, and reference electrode, respectively.

A constant potential of −1.9 V, at which silicon and uranium are able to be electrodeposited at the same time, was applied to the tungsten substrate (a working electrode) for an hour to electrodeposit SiU. As the chronoamperometric method proceeded, the oxidized silicon element and uranium chloride dissolved in the high-temperature molten salt were reduced into silicon-uranium, as represented by the following electrochemical formula.

xSi⁴⁺+yU³⁺→SiₓU_{y}(s)

The reduced silicon-uranium electrodeposit was investigated using a scanning electron microscope and an EDX method. As a result, it was revealed that SiU was electrodeposited onto the working electrode, as shown in FIG. 9.

According to the embodiments of the present invention, cost and processing time may be significantly reduced by reducing the number of processes in preparing a semiconductor, a solar cell, a secondary battery, a fuel cell, a water electrolysis cell, a nuclear fuel of a nuclear reactor, a target for producing a radioactive isotope, a catalyst for chemical reaction, or, a sensor, thereby enhancing price competitiveness of products.

That is, the present invention has advantageous effects of significantly reducing the number of processes, cutting cost, and manufacturing time by direct coating of the oxidized silicon elements on an electrode surface, followed by electrochemical reduction of the coating for preparation of a silicon thin film required for a device such as a semiconductor, a solar cell or a secondary battery.

It will be apparent to those skilled in the art that various modifications can be made to the above-described embodiments of the present invention without departing from the scope of the invention. Thus, it is intended that the present invention cover all such modifications provided they come within the scope of the appended claims and their equivalents.

What is claimed is:

1. A method of preparing a silicon thin film, the method comprising:
providing a silicon oxide film over a substrate; and
electrochemically reducing silicon oxide contained in the silicon oxide film in a liquid electrolyte to form a porous film.

2. The method of claim 1, wherein providing the silicon oxide film comprises:
providing silicon oxide liquid comprising silicon oxide;
applying the silicon oxide liquid on the substrate to provide the silicon oxide film over the substrate; and
sintering the silicon oxide film.

3. The method of claim 2, wherein the silicon oxide liquid or the liquid electrolyte comprises a compound comprising at least one selected from the group consisting of carbon (C), boron (B), nitrogen (N), aluminum (Al), phosphorus (P), sulfur (S), gallium (Ga), arsenic (As), selenium (Se), indium (In), tin (Sn), antimony (Sb), tellurium (Te),
wherein the resulting silicon thin film further comprises at least one selected from the group consisting of carbon (C), boron (B), nitrogen (N), aluminum (Al), phosphorus (P), sulfur (S), gallium (Ga), arsenic (As), selenium (Se), indium (In), tin (Sn), antimony (Sb), tellurium (Te).

4. The method of claim 2, wherein applying the silicon oxide liquid comprises at least one method selected from the group consisting of spin coating, inkjet coating, casting, brushing, dipping, physical vapor deposition, and chemical vapor deposition.

5. The method of claim 2, wherein the silicon oxide liquid or the liquid electrolyte comprises a compound comprising at least one selected from the group consisting of lithium (Li), sodium (Na), potassium (K), rubidium (Rb), cesium (Cs), francium (Fr), beryllium (Be), magnesium (Mg), calcium (Ca), strontium (Sr), barium (Ba), radium (Ra), boron (B), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), arsenic (As), selenium (Se), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), lanthanum (La), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), actinium (Ac), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), thorium (Th), protactinium (Pa), uranium (U), neptunium (Np), plutonium (Pu), americium (Am), and curium (Cm).

6. The method of claim 1, further comprising removing the liquid electrolyte from the silicon thin film, wherein removing the liquid electrolyte involves at least one of boiling the liquid electrolyte under a pressure of less than 760 Torr and washing the liquid electrolyte with liquid containing water.

7. The method of claim 1, wherein providing the silicon oxide liquid comprises mixing silicon oxide with a solvent.

8. The method of claim 7, wherein mixing silicon oxide comprises mixing at least one material selected from the group consisting of sand, glass, quartz, rock, ceramic, silica (SiO₂), tetraethoxysilane (TEOS), tetramethoxysilane, a silicon alkoxy, and silicon tetrachloride.

9. The method of claim 7, wherein the solvent comprises in at least one selected from the group consisting of water, lithium hydroxide, sodium hydroxide, potassium hydroxide, calcium hydroxide, rubidium hydroxide, strontium hydroxide, cesium hydroxide, barium hydroxide, hydrofluoric acid, hydrochloric acid, sulfuric acid, nitric acid, phosphoric acid, sodium silicate, ethanol, methanol, benzene, toluene, hexane, pentane, cyclohexane, chloroform, diethyl ether, dichloromethane (DCM), tetrahydrofuran (THF), ethyl acetate, acetone, acetonitrile, dimethylformamide (DMF), dimethylsulfoxide (DMSO), and propylene carbonate.

10. The method of claim 1, wherein the substrate comprises at least one selected from the group consisting of a metal, carbon, and silicon.

11. The method of claim 1, wherein the liquid electrolyte comprises at least one selected from the group consisting of LiCl, KCl, NaCl, RbCl, CsCl, FrCl, CaCl₂, MgCl₂, SrCl₂, BaCl₂, AlCl₃, ThCl₃, LiF, KF, NaF, RbF, CsF, FrF, CaF₂, MgF₂, SrF₂, BaF₂, AlF₃, ThF₃, LiPF₆, LiBr, NaBr, KBr, RbBr, CsBr, FrBr, LiI, NaI, Kl, RbI, CsI, and FrI.

12. The method of claim 1, wherein the liquid electrolyte comprises at least one selected from the group consisting of acetonitrile, tetrafluoroborate, 1-butyl-3-methylimidazolium chloride, 1-butyl-1-methylpyrrolidinium bis(trifluoromethylsulfonyl)imide, 1-butylpyridinium chloride, choline chloride, 1-butyl-3-methylimidazolium chloride, dimethylethylphenylammonium bromide, dimethylformamide, dimethyl sulfone, dimethyl sulfoxide, ethylene carbonate, dimethyl carbonate, ethyl-methyl carbonate, ethylene-diaminetetra-acetic acid tetrasodium, ethylene glycol, 1-ethyl-3-methylimidazolium, 1-octyl-1-methyl-pyrrolidinium bis(trifluoromethylsulfonyl)imide, hexafluorophosphate, 1-propyl-3-methylimidazolium chloride, trihexyl-tetradecyl-phosphonium bis(trifluoromethylsulfonyl)imide, tetrabutylammonium chloride bis(trifluoromethylsulfonyl)imide, tetrahydrofuran, and trimethylphenylammonium chloride.

13. The method of claim 1, further comprising sintering the porous film to form a silicon thin film.

14. The method of claim 13, wherein sintering the porous silicon film comprises heating the porous silicon film at 1,350° C. or higher for 1 second or more.

15. The method of claim 1, wherein the electrochemical reduction is performed between −2.5 V and 0 V vs. Ag|Ag⁺.

16. A method of preparing a silicon film, comprising:
(a) dissolving at least one material selected from the group consisting of sand, glass, quartz, rock, ceramic, silica (SiO₂), tetraethoxysilane (TEOS), tetramethoxysilane, and a silicon alkoxy in a solvent to obtain a oxidized silicon element solution;
(b) preparing a powder of silica, fluorinated silica (SiFxOy) or hydroxo-fluorinated silicon (SiFₓOH_{y}) by evaporating, drying, extracting, or filtering the oxidized silicon element solution; and
(c) electrochemically reducing the silica, fluorinated silica (SiFxOy) or hydroxo-fluorinated silicon (SiFₓOH_{y}) dissolved in a liquid electrolyte to electrodeposit silicon onto a substrate.

17. The method of claim 16, wherein the solvent in step (a) is at least one selected from the group consisting of water, hydrofluoric acid, lithium fluoride, sodium fluoride, potassium fluoride, rubidium fluoride, cesium fluoride, beryllium fluoride, magnesium fluoride, calcium fluoride, strontium fluoride, barium fluoride, ammonium fluoride, lithium hydroxide, sodium hydroxide, potassium hydroxide, rubidium hydroxide, cesium hydroxide, beryllium hydroxide, magnesium hydroxide, calcium hydroxide, strontium hydroxide, and barium hydroxide.

18. The method of claim 16, wherein at least one selected from the group consisting of uranium (U), thorium (Th), plutonium (Pu), carbon (C), boron (B), nitrogen (N), aluminum (Al), phosphorus (P), sulfur (S), gallium (Ga), arsenic (As), selenium (Se), indium (In), tin (Sn), antimony (Sb), tellurium (Te), and their oxidized elements thereof is further added to the liquid electrolyte of step (c).

19. The method of claim 16, wherein the liquid electrolyte in step (c) is at least one high-temperature molten salt selected from the group consisting of LiCl, KCl, NaCl, RbCl, CsCl, FrCl, CaCl₂, MgCl₂, SrCl₂, BaCl₂, AlCl₃, ThCl₃, LiF, KF, NaF, RbF, CsF, FrF, CaF₂, MgF₂, SrF₂, BaF₂, AlF₃, ThF₃, LiPF₆, LiBr, NaBr, KBr, RbBr, CsBr, FrBr, LiI, NaI, Kl, RbI, CsI, and FrI.

20. The method of claim 16, wherein the liquid electrolyte in step (c) is at least one selected from the group consisting of acetonitrile, tetrafluoroborate, 1-butyl-3-methylimidazolium chloride, 1-butyl-1-methylpyrrolidinium bis(trifluoromethylsulfonyl)imide (1-butyl-1-methylpyrrolidinium bis(trifluoromethlylsulfonyl)imide), 1-butylpyridinium chloride, choline chloride, 1-butyl-3-methylimidazolium chloride, dimethylethylphenylammonium bromide, dimethylformamide, dimethyl sulfone, dimethyl sulfoxide, ethylene carbonate, dimethyl carbonate, ethyl-methyl carbonate, ethylene-diaminetetra-acetic acid tetrasodium, ethylene glycol, 1-ethyl-3-methylimidazolium, 1-octyl-1-methyl-pyrrolidinium bis(trifluoromethylsulfonyl)imide, hexafluorophosphate, 1-propyl-3-methylimidazolium chloride, trihexyl-tetradecyl-phosphonium bis(trifluoromethylsulfonyl)imide, tetrabutylammonium chloride bis(trifluoromethylsulfonyl)imide, tetrahydrofuran, and trimethylphenylammonium chloride.

21. The method of claim 16, wherein the electrochemical reduction of step (c) is performed between −2.5 and 0 V vs. Ag|Ag⁺.

22. A method of preparing a thin film, the method comprising:
providing, over a substrate, an oxide film comprising one selected from the group consisting of lithium (Li), sodium (Na), potassium (K), rubidium (Rb), cesium (Cs), francium (Fr), beryllium (Be), magnesium (Mg), calcium (Ca), strontium (Sr), barium (Ba), radium (Ra), boron (B), carbon (C), aluminum (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), arsenic (As), selenium (Se), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), lanthanum (La), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), actinium (Ac), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), thorium (Th), protactinium (Pa), uranium (U), neptunium (Np), plutonium (Pu), americium (Am), and curium (Cm); and
electrochemically reducing the oxide contained in the oxide film in a liquid electrolyte to form a film.
